(19) United States
(12) Patent Application Publication
(10) Pub. No.: US 2024/0282643 A1
(43) Pub. Date: Aug. 22, 2024

(54) PLATING DEFECTS ESTIMATING METHOD AND SEMICONDUCTOR DEVICE MANUFACTURING METHOD

(71) Applicant: HITACHI POWER SEEMICONDUCTOR DEVICE, LTD., Hitachi-shi, Ibaraki (JP)

(72) Inventors: Reo Kobayashi, Tokyo (JP); Toshihito Tabata, Hitachi-shi, Ibaraki (JP); Kanya Hamada, Hitachi-shi, Ibaraki (JP)

(73) Assignee: HITACHI POWER SEEMICONDUCTOR DEVICE, LTD., Hitachi-shi, Ibaraki (JP)

(21) Appl. No.: 18/570,706

(22) PCT Filed: May 9, 2022
(86) PCT No.: PCT/JP2022/019638

§ 371 Date: Dec. 15, 2023

(30) Foreign Application Priority Data
Sep. 29, 2021 (JP) 2021-159508

(51) Int. Cl. H01L 21/66; G01N 21/84; G01N 21/95; H01L 21/3205

(52) U.S. Cl. CPC H01L 22/12; G01N 21/8422; G01N 21/9501; H01L 21/32051

(57) ABSTRACT

A plating defects estimating method comprising a measuring step of measuring physical properties of a surface of an underlayer before a plating pre-treatment step of carrying out a plating pre-treatment on the underlayer; and an estimating step of estimating a degree of development of spikes on the underlayer, the spikes resulting from plating, based on the measured physical properties. A semiconductor device manufacturing method, comprising:
an underlayer forming step of forming an underlayer on a surface of a semiconductor wafer; a plating pre-treatment step of carrying out a plating pre-treatment on the underlayer; a plating step of plating the underlayer subjected to the pre-treatment; a measuring step of measuring physical properties of a surface of the underlayer before the plating pre-treatment step; and an estimating step of estimating a degree of development of spikes on the underlayer, the spikes resulting from plating, based on the measured physical properties.

### TECHNICAL FIELD

The present invention relates to a plating defects estimating method of estimating a degree of development of spikes on an underlayer, the spikes resulting from plating, and a semiconductor device manufacturing method using the plating defects estimating method.

### BACKGROUND ART

Conventionally, various plating processes have been developed to form a homogeneous plating film with less defects. Electroplating and electroless plating are used for various purpose, such as improving the appearance of a product, improving wear resistance, corrosion resistance, and the like, and constructing a fine structure of a semiconductor device. Nickel plating is excellent in mechanical properties and corrosion resistance and offers better adhesion, and is therefore used in various fields.

PTL 1 describes a black bright material formed by using an electroless nickel plating method or an electroless nickel alloy plating method, and a method of manufacturing the black bright material. As a base material, an aluminum piece or the like is cited. It is stated in PTL1 that adjusting the reflectance of the black bright material in reflection of visible light offers an intended sense of brightness.

PTL 2 describes a roughened nickel plating plate. As a base material, an aluminum plate or the like is cited. It is stated in PTL2 that adjusting the brightness of the surface of a roughened nickel layer offers excellent adhesion.

PTL 3 describes a wear-resistant member having a hard plating film and a power transmission component using the member. The hard plating film is formed of Ni—P plating. As a base material, an aluminum alloy or the like is cited. It is stated in PTL3 that adjusting the crystallite average size of the Ni—P plating film ensures wear resistance, fatigue life, plating adhesion, and the like.

PTL 4 describes a spike phenomenon that occurs during nickel plating. It describes a phenomenon that when an aluminum substrate is etched into a recessed shape in a stage of a plating pre-treatment, nickel enter recesses because of the nickel plating and forms a nickel pattern observed as spikes. It is stated in PTL4 that a metal substitution treatment liquid containing quaternary ammonium hydroxide suppresses attack on the aluminum substrate, thus suppressing development of cracks.

### CITATION LIST

### Non-Patent Literature

PTL 1: JP 2002-363771 A
PTL 2: WO 2020/017655 A
PTL 3: JP 2007-023316 A
PTL 4: JP 2009-127101 A

### SUMMARY OF INVENTION

### Technical Problem

In a manufacturing process for a semiconductor device, plating may be applied to a surface of an electrode to which a semiconductor element is connected. Currently, in various fields including manufacturing of semiconductor devices, knowing a degree of development of plating defects at an early stage is in demand. If a plating defect is found during a product inspection after plating, the plating defect renders the whole plating step useless, which affects the yield significantly. This problem has led to a demand that the degree of development of plating defects be estimated not from an inspection of a plating film itself but from the physical properties of a plating base.

In PTLs 1 to 3, the reflectance, brightness, crystallite size, and the like are adjusted in order to form a proper plating film. These physical properties are, however, the physical properties of the surface of the plating film, and are the physical properties that are not understood until plating is completed. Methods of measuring the physical properties of the surface of the plating film, the methods being described in PTLs 1 to 3, cannot achieve an improvement in the yield including an improvement in a plating step. Hence a technique is demanded by which the degree of development of plating defects is estimated before the plating step and whether or not to execute the plating step can be determined according to the risk of development of plating defects.

Among problems related to plating defects, a spike phenomenon is a particular problem to deal with. The spike phenomenon is a phenomenon that the plating film enters recesses on the surface of the base to form a spike-like pattern. The spike phenomenon occurs in such a way that when a metal making up the base undergoes pitting corrosion during plating pre-treatment, a plating metal deposits in pits resulting from the pitting corrosion during plating. As a result, a great number of spikes of projections or needle-like shapes are formed at an interface between the base and the plating film. Formation of spikes brings a concern that the adhesion of the plating film may drop or electrical short circuit may occur, which may lead to a shorter product life.

An object of the present invention is to provide a plating defects estimating method by which a degree of development of spikes resulting from plating can be estimated before formation of a plating film, and to provide a semiconductor device manufacturing method using the plating defect estimating method.

### Solution to Problem

In order to solve the above problems, a plating defects estimating method according to the present invention includes: a measuring step of measuring physical properties of a surface of an underlayer before a plating pre-treatment step of carrying out a plating pre-treatment on the underlayer; and an estimating step of estimating a degree of development of spikes on the underlayer, the spikes resulting from plating, based on the measured physical properties.

A semiconductor device manufacturing method according to the present invention includes: an underlayer forming step of forming an underlayer on a surface of a semiconductor wafer; a plating pre-treatment step of carrying out a plating pre-treatment on the underlayer; a plating step of plating the underlayer subjected to the pre-treatment; a measuring step of measuring physical properties of a surface of the underlayer before the plating pre-treatment step; and an estimating step of estimating a degree of development of spikes on the underlayer, the spikes resulting from plating, based on the measured physical properties.

### Advantageous Effects of Invention

The present invention can provide a plating defects estimating method by which a degree of development of spikes resulting from plating can be estimated before formation of a plating film, and a semiconductor device manufacturing method using the plating defect estimating method.

### BRIEF DESCRIPTION OF DRAWINGS

FIG. 1 is a flowchart of a plating defects estimating method according to an embodiment of the present invention.

FIG. 2 is a cross-sectional view schematically showing an example of a configuration of a semiconductor device.

FIG. 3A depicts a semiconductor device manufacturing method (a state of a p-type semiconductor layer being formed).

FIG. 3B depicts the semiconductor device manufacturing method (a state of an oxide film being formed).

FIG. 3C depicts the semiconductor device manufacturing method (a state of a metal underlayer being formed).

FIG. 4A depicts the semiconductor device manufacturing method (a state of a resin layer being formed).

FIG. 4B depicts the semiconductor device manufacturing method (a state of the metal underlayer being formed).

FIG. 4C depicts the semiconductor device manufacturing method (a state of plating layers being formed).

FIG. 5 is a flowchart of a process of electroless plating.

FIG. 6 depicts a relationship between measurement results of the brightness of the surface of the underlayer and evaluation results of a degree of development of spikes.

FIG. 7 depicts a relationship between measurement results of reflectance on the surface of the underlayer and evaluation results of the degree of development of spikes.

FIG. 8 depicts a relationship between measurement results of the crystallite diameter of the surface of the underlayer and evaluation results of the degree of development of spikes.

### DESCRIPTION OF EMBODIMENTS

Hereinafter, a plating defects estimating method according to an embodiment of the present invention and a semiconductor device manufacturing method using the plating defects estimating method will be described with reference to the drawings. In the following description, the same constitutional elements in drawings will be denoted by the same reference signs and redundant description will be omitted.

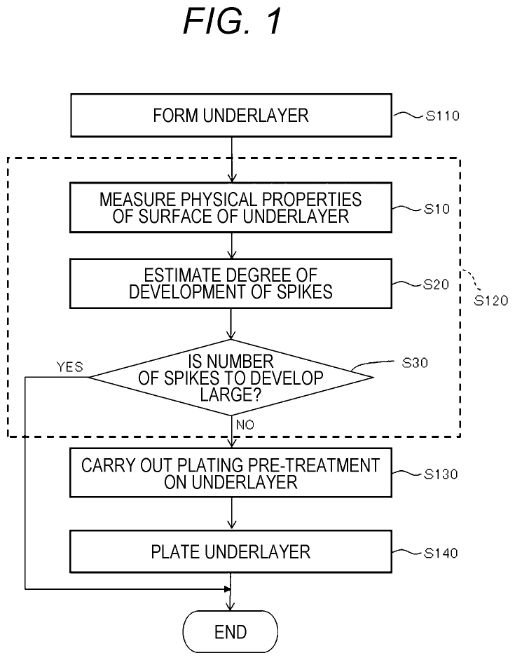

FIG. 1 is a flowchart of a plating defects estimating method according to an embodiment of the present invention. As shown in FIG. 1, the plating defects estimating method according to this embodiment is executed as a plating defects estimating step S120, together with an underlayer forming step S110, a plating pre-treatment step S130, and a plating step S140. The plating defects estimating step S120 includes a measuring step S10, an estimating step S20, and a determining step S30. According to a result of the determining step S30, the plating pre-treatment step S130 and plating step S140 as preset steps are executed or the plating pre-treatment step S130 and plating step S140 as preset steps are stopped.

The plating defects estimating method according to this embodiment is a method of estimating a degree of development of spikes resulting from plating. By the plating defects estimating method according to this embodiment, the degree of development of spikes is estimated from the physical properties of the surface of an underlayer to be plated. The degree of development of spikes can be estimated without actually forming a plating film, that is, can be estimated before formation of the plating film. Whether or not to carry out plating, therefore, can be determined before formation of the plating film.

Spikes are a result of a spike phenomenon that the plating film enters recesses on the surface of the underlayer to form a spike-like pattern. When the underlayer formed of metal undergoes pitting corrosion during a plating pre-treatment, a plating metal deposits in pits created by the pitting corrosion during plating, thus forming spikes. Spikes, which are formed of the plating metal, develop along an interface between the underlayer and the plating film, as a great number of projections or needle-like shapes projecting toward the underlayer.

Formation of spikes brings a concern that the adhesion of the plating film may drop or an electrical short circuit may be created via the underlayer. These concerns amount to a concern that the service life of a plated product may get shorter. According to the plating defects estimating method of this embodiment, however, the degree of development of spikes can be estimated before formation of the plating film and therefore whether or not to execute the plating pre-treatment step S130 and the plating step S140 can be determined in advance, based on a result of estimation of the degree of development of spikes. Hence a product yield can be improved.

The degree of development of spikes can be evaluated, for example, as the number of spikes. The number of spikes can be defined as the number of spikes that intersect the interface between the underlayer and the plating film per unit length of a virtual straight line extending along the interface. For example, when the number of spikes per 1 μm-long segment of the interface is one or so, the degree of development of spikes can be said to be low. If the number of spikes per the same exceeds several spikes, however, the degree of development of spikes can be said to be high. In another approach, the degree of development of spikes, i.e., the number of spikes may also be defined as the number of spikes that intersect the interface between the underlayer and the plating film per unit area.

According to the plating defects estimating method of this embodiment, a correlation between the physical properties of the surface of the underlayer and the degree of development of spikes is obtained in advance before the estimation is made. The correlation is obtained by using a plating material of which a degree of development of spikes is already known, that is, a plating material having developed spikes already. By measuring the physical properties of the surface of the underlayer of the plating material having developed spikes already and measuring the degree of development of spikes as well, the correlation between the physical properties of the surface of the underlayer and the degree of development of spikes is obtained.

Estimation of the degree of development of spikes is made on a material-to-be-plated not subjected to the plating pre-treatment yet. When the physical properties of the surface of the underlayer are measure for the material-to-be-plated (underlayer) of which a degree of development of spikes is unknown and a result of the measurement is applied to a correlation obtained by using a plating material of which a degree of development of spikes is known, the approximate number of spikes per unit length of the interface between the underlayer and the plating layer is obtained as a result of estimation of the degree of development of spikes.

The underlayer forming step S110 is a step of forming the underlayer made of metal on the material-to-be-plated, which is to be subjected to plating.

Examples of a metal making up the underlayer include aluminum, aluminum alloy, magnesium, and magnesium alloy. These metals are base metals that have a standard electrode potential lower than that of zinc and that are easily electrochemically corroded. Because these metals are apt to undergo pitting corrosion that is a cause for the spike phenomenon, estimating the degree of development of spikes on the underlayer made of these metals allows a wide improvement in the product yield.

The measuring step S10 is a step of measuring the physical properties of the surface of the underlayer before the plating pre-treatment. At the pre-treatment step S130, there is a possibility that pitting corrosion, the cause for the spike phenomenon, may occur, depending on the type of a metal making up the underlayer and the type of an acid solution, an alkali solution, a chemical solution, or the like used in the treatment. At the measuring step S10, the physical properties of the surface of the underlayer are measured, and the measured physical properties are used as data for estimating the degree of development of pitting corrosion and the degree of development of spikes before pitting corrosion actually occurs.

As the measuring step S10, either a step of carrying out optical measurement of the surface of the underlayer or a step of carrying out X-ray diffraction measurement of the surface of the underlayer can be executed. In the optical measurement, reflectance on the surface of the underlayer or the brightness of the surface of the underlayer is measured. In the X-ray diffraction measurement, an X-ray diffraction spectrum is measured, and the full width at half maximum at a given peak of the spectrum of the metal making up the underlayer is obtained, and then the crystallite diameter of the surface of the underlayer is obtained by calculations using the full width at half maximum.

The inventors of the present invention have confirmed that the reflectance on the surface of the underlayer, the brightness of the surface of the underlayer, and the crystallite diameter of the surface of the underlayer indirectly indicate a possibility of occurrence of pitting corrosion and that they have a correlation with the degree of development of spikes. By measuring these physical properties of the material-to-be-plated of which the degree of development of spikes is known, a correlation between the physical properties and the degree of development of spikes is obtained. Thus, by measuring these physical properties of the material-to-be-plated of which the degree of development of spikes is unknown and applying the measured physical properties to the obtained correlation, the degree of development of spikes that is unknown can be estimated.

The estimating step S20 is a step of estimating the degree of development of spikes on the underlayer, the spikes resulting from plating, based on the measured physical properties of the surface of the underlayer. At the estimating step S20, measurement results of the material-to-be-plated of which the degree of development of spikes is unknown are applied to the correlation obtained by using the plating material of which the degree of development of spikes is known, and a result of estimation of the degree of development of spikes of the material-to-be-plated is obtained.

The correlation between the physical properties of the surface of the underlayer and the degree of development of spikes can be plotted on a biaxial graph or the like. This correlation is transformed into a linear correlation through a regression analysis using a least squares method or the like, and the linear correlation can be applied to the estimation. The correlation can be applied to the estimation also by using a machine learning method. The result of estimation of the degree of development of spikes of the material-to-be-plated can be obtained as an estimate of the approximate number of spikes per unit length of the interface between the underlayer and the plating film, an estimated range of the approximate number, or the like.

At the estimating step S20, to estimate the degree of development of spikes, a regression model equation representing a linear correlation or the like can be created from the correlation obtained by using the plating material of which the degree of development of spikes is known. Measurement results of the physical properties of the surface of the underlayer for the material-to-be-plated of which the degree of development of spikes is unknown are substituted in the regression model equation. This allows calculation of an estimate of the approximate number of spikes per unit length of the interface between the underlayer and the plating film, an estimated range of the approximate number, and the like.

The determining step S30 is a step of comparing the estimated degree of development of spikes with a given reference value and determining whether the number of spikes expected to develop is large or small. By comparing the result of estimation of the degree of development of spikes of the material-to-be-plated with a given reference value or the like set according to a product, different treatments on the material-to-be-plated can be specified in accordance with spike development risks.

As the reference value for the comparison, any given numerical value or numerical value range can be set, which represents the number of spikes per unit length of the interface between the underlayer and the plating film, the range of the number of spikes, and the like. For example, in the case of a plating layer formed on an electrode to which a semiconductor element is connected, the number of spikes per 1 μm-long segment of the interface exceeding several spikes raises a high possibility that an electrical short circuit via the underlayer is created. It is therefore preferable that as the reference value for the comparison, the number of spikes per 1 μm-long segment of the interface be 1 or 0.5.

As shown in FIG. 1, when the result of estimation of the degree of development of spikes is larger than a threshold (YES at the determining step S30), the plating pre-treatment step S130 and plating step S140 as preset steps can be stopped. These steps may not be simply stopped and abandoned. Instead, the details of the plating pre-treatment step S130 may be made different between a case of the result of estimation of the degree of development of spikes being larger than the threshold and a case of the same being smaller than the threshold. One example of making the details of the plating pre-treatment step S130 different is to execute the plating pre-treatment step S130 under conditions different from conditions under which the plating pre-treatment step S130 as the preset step is executed. Another example of making the details of the plating pre-treatment step S130 different is to execute, as an additional plating pre-treatment step (plating pre-treatment step S130), a resurfacing treatment step of carrying out a proper resurfacing treatment on the surface of the underlayer, the resurfacing treatment being one of heat treatment, mechanical polishing, chemical polishing, electrolytic polishing, and the like, before execution of the plating pre-treatment step S130 as the preset step and then execute the plating pre-treatment step S130 as the preset step on the material-to-be-plated subjected to the resurfacing treatment, in the same manner as in the normal case. Then, the material-to-be-plated can be subjected to the plating step S140. When the result of estimation of the degree of development of spikes is smaller than the threshold (NO at the determining step S30), the plating pre-treatment step S130 and plating step S140 as preset steps can be executed.

The plating pre-treatment step S130 is a step of carrying out a plating pre-treatment on the underlayer made of metal. At the plating pre-treatment step S130, the surface of the underlayer before being plated is subjected to a cleaning treatment or a surface treatment using an acid solution, an alkali solution, and other chemical solutions. At the plating pre-treatment step S130, the metal making up the underlayer is electrochemically corroded to cause pitting corrosion that is the cause for spike development. The plating pre-treatment step S130 may be a single step or may be composed of a plurality of steps.

Treatments making up the plating pre-treatment step S130 include a degreasing/cleaning treatment of removing fats and oils from the surface of the underlayer, an alkali cleaning treatment of removing an oxide film and the like from the surface of the underlayer, using an alkali solution, an acid cleaning treatment of removing smut or the like, using an acid solution, and a zincate treatment of replacing a surface film on the underlayer with a zinc film.

The zincate treatment is carried out when the underlayer is made of aluminum, aluminum alloy, or the like. By the zincate treatment, an oxide film is removed from surface of the underlayer and a zinc film is formed temporarily on the surface of the underlayer. As a result of formation of the zinc film, replacement of zinc with a plating metal occurs during plating, which facilitates deposition of a plating film. In the zincate treatment step, a zincate liquid that corrodes metal is used.

The plating step S140 is a step of plating the surface of the underlayer. A plating method is either electrolytic plating or electroless plating. However, from the viewpoint of forming a plating layer highly uniform in thickness and composition and of reducing the cost of the plating step, electroless plating is more preferable.

As the plating metal forming the plating layer, nickel, copper, chromium, iron, tin, silver, palladium, platinum, gold, an alloy of these metals, or the like can be used. When these plating metals are used, for each type of plating metal, a correlation between the degree of development of spikes, the reflectance on the surface of the metal, the brightness of the surface of the metal, and the crystallite diameter of the surface of the metal is obtained in advance.

According to the above plating defects estimating method of this embodiment, the degree of development of spikes is estimated from the physical properties of the surface of the underlayer and therefore the degree of development of spikes can be estimated before formation of the plating film. This makes it possible to plate only the material-to-be-plated that is assumed to develop fewer spikes, in which case a drop in the adhesion of the plating film or electrical short circuit via the underlayer hardly occurs and therefore a product with a long service life can be obtained. In a case where estimation of the degree of development of spikes indicates development of many spikes, the plating step may be stopped or conditions under which the plating pre-treatment step is executed may be changed. This improves the product yield.

A semiconductor device manufacturing method using the plating defects estimating method will then be described with reference to drawings.

The plating defects estimating method can be incorporated in a manufacturing process for a semiconductor device. The plating defects estimating method can be used to estimate the degree of development of spikes on the plating layer that is formed during the manufacturing process for the semiconductor device.

As shown in FIG. 1, the semiconductor device manufacturing method includes the underlayer forming step S110, the plating defects estimating step S120, the plating pre-treatment step S130, and the plating step S140. The plating defects estimating step S120, which is the above-described plating defects estimating process, includes the measuring step S10, the estimating step S20, and the determining step S30.

The semiconductor device manufacturing method includes a semiconductor element forming step (not illustrated). The semiconductor element forming step is a step of forming a semiconductor element, such as a switching element or a diode element, on a semiconductor wafer.

At the underlayer forming step S110, the underlayer made of metal is formed on the semiconductor wafer. The underlayer can be formed by sputtering, vapor deposition, chemical vapor deposition (CVD), or the like. The underlayer makes up, for example, a part of an electrode of the semiconductor element. The underlayer is formed on the surface of the semiconductor wafer or on the surface of a functional layer, such as the semiconductor element or an insulating film formed on the surface of the semiconductor wafer.

The semiconductor device is a semiconductor chip or a semiconductor module. When the semiconductor device is a semiconductor module, the manufacturing method may include a step of electrically connecting a semiconductor chip to an insulating substrate. When the semiconductor device is the semiconductor module, the semiconductor chip is mounted on the insulating substrate and an electrode formed on the semiconductor chip is electrically connected to a wiring line formed on the insulating substrate to form a circuit, and then these elements and circuit are enclosed in a housing and are sealed with an insulating sealing resin to complete the semiconductor device.

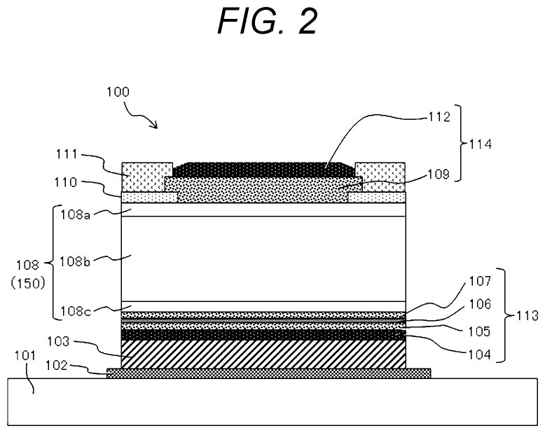

FIG. 2 is a cross-sectional view schematically showing an example of a configuration of the semiconductor device.

FIG. 2 shows a semiconductor device 100 including a freewheel diode, which is a semiconductor element. The semiconductor device 100 includes electrodes formed on a front surface and a back surface of a semiconductor chip, respectively, the electrodes having plating layers 104 and 112 formed for electrical connection, respectively. One or both of the plating layers 104 and 112 included in the semiconductor device 100 is a layer of which a degree of development of spikes is estimated.

FIG. 2 shows an example in which a silicon substrate that is an n-type semiconductor is used as a substrate of the semiconductor element. However, a silicon substrate that is a p-type semiconductor may also be used as the substrate of the semiconductor element. Besides a silicon-based semiconductor, a wide-gap semiconductor made of silicon carbide (SiC), gallium nitride (GaN), gallium oxide (GaO), or the like may also be used.

FIG. 2 shows the semiconductor device 100 including the freewheel diode. The semiconductor device 100, however, may include other semiconductor elements, such as a metal-oxide-semiconductor field-effect transistor (MOSFET) and an insulated gate bipolar transistor (IGBT).

As shown in FIG. 2, the semiconductor device 100 includes an insulating substrate 101, a conductive member 102, a semiconductor substrate 108, a cathode electrode 113, an anode electrode 114, and a resin layer 111. The cathode electrode 113 is formed of, for example, a plating layer 104, a metal underlayer 105, a copper diffusion prevention layer 106, and a metal layer 107. The anode electrode 114 is formed of, for example, a metal underlayer 109 and a plating layer 112.

The semiconductor substrate 108 is of a structure in which a p-type semiconductor layer 108a, an n⁻-type drift layer 108b, and an n+-type drift layer 108c are stacked in descending order from an upper surface side toward a lower surface side. By joining these semiconductor layers together, the semiconductor substrate 108 is formed as a semiconductor element 150. The p-type semiconductor layer 108a is doped with a p-type impurity. The n⁻-type drift layer 108b is doped with a low-concentration n-type impurity. The n+-type drift layer 108c is doped with a high-concentration n-type impurity.

On a lower surface of the semiconductor substrate 108, the metal layer 107, the copper diffusion prevention layer 106, the metal underlayer 105, and the plating layer 104 are stacked in descending order from the upper surface side toward the lower surface side. The metal layer 107, the copper diffusion prevention layer 106, the metal underlayer 105, and the plating layer 104 form the cathode electrode 113, which is an electrode structure on a cathode side. These layers and the semiconductor substrate 108 are electrically connected to each other.

The metal layer 107 forms a main part of the electrode, and is made of aluminum or an aluminum alloy, such as an aluminum-silicon alloy. The copper diffusion prevention layer 106 is a layer that prevents thermally diffusing copper from entering the semiconductor substrate 108, and is made of titanium, titanium nitride, tungsten, titanium tungsten, nickel, or the like. Providing the copper diffusion prevention layer 106 prevents copper with a high diffusion coefficient from diffusing from a junction layer 103 or the like into the semiconductor substrate 108. This improves the long-term reliability of the semiconductor element 150.

The metal underlayer 105 is an underlayer to be plated, and is made of aluminum or an aluminum alloy, such as an aluminum-silicon alloy. The plating layer 104 is a plating film formed by plating, and is made of a nickel-phosphorus alloy (Ni—P alloy), a nickel-boron alloy (Ni—B alloy), or the like. It is preferable, from the viewpoint of uniformity, corrosion resistance, and the like, that the plating layer 104 be made of a nickel-phosphorus alloy.

On an upper surface of the semiconductor substrate 108, an oxide film 110 is formed. The oxide film 110 is formed on a part of the upper surface of the semiconductor substrate 108. On the upper surface of the semiconductor substrate 108, a contact region in which the semiconductor substrate 108 is not covered with the oxide film 110 is formed, and therefore the semiconductor substrate 108 is partially exposed. On the exposed part of the upper surface of the semiconductor substrate 108, the metal underlayer 109 and the plating layer 112 are stacked in ascending order. The metal underlayer 109 and plating layer 112 and the semiconductor substrate 108.are electrically connected to each other.

The oxide film 110 is formed along the periphery of the metal underlayer 109, creating a termination region in which the semiconductor substrate 108 is covered with the oxide film 110. On a surface of the oxide film 110 encircling the metal underlayer 109, the resin layer 111 is formed. The oxide film 110 is an electrically insulating layer and is made of silicon dioxide. The resin layer 111 is an electrically insulating layer and is made of an insulating resin, such as polyimide.

The metal underlayer 109 is an underlayer to be plated, and is made of aluminum or an aluminum alloy, such as an aluminum-silicon alloy or an aluminum-copper alloy.

The plating layer 112 is a plating film formed by plating, and is made of a nickel-phosphorus alloy (Ni—P alloy), a nickel-boron alloy (Ni—B alloy), or the like. It is preferable, from the viewpoint of uniformity, corrosion resistance, and the like, that the plating layer 112 be made of a nickel-phosphorus alloy.

The semiconductor element 150, which is formed as the semiconductor substrate 108, is stacked together with the cathode electrode 113, the anode electrode 114, the resin layer 111, and the like to constitute a semiconductor chip, which is mounted on the insulating substrate 101. To an upper surface of the insulating substrate 101, the conductive member 102 is joined. The plating layer 104 of the cathode electrode 113 is joined to an upper surface of the conductive member 102 via the junction layer 103. The plating layer 104 is electrically connected to the conductive member 102 and to the semiconductor substrate 108.

The insulating substrate 101 is a substrate that supports the semiconductor element 150 and that electrically insulates the semiconductor element 150 from the surroundings, and is made of, for example, ceramics. The conductive member 102 has a pattern serving as a wiring line on the cathode side, and is made of copper. The junction layer 103 thermally connects the semiconductor element 150 to the insulating substrate 101, and is formed as, for example, a metal sintered body made of copper, cupric oxide, silver, or the like. The junction layer 103 may be formed as a solder layer.

The plating layer 112 of the anode electrode 114 is not covered with the resin layer 111 and is exposed on the top of the semiconductor device 100. To an upper surface of the plating layer 112, a wire (not illustrated) serving as a wiring line on the anode side is electrically connected. The semiconductor element 150 is connected to a different element or the like by wire bonding to form a prescribed circuit.

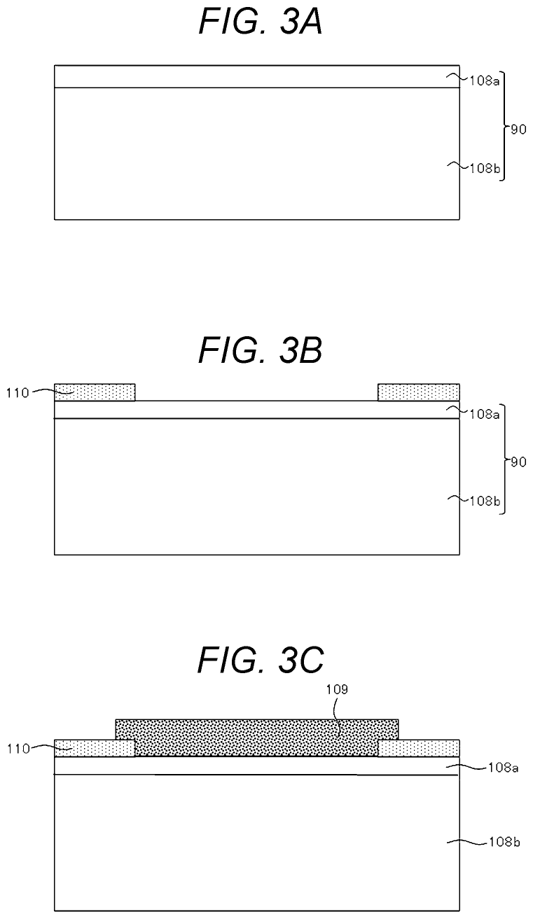

FIGS. 3A to 3C depict the semiconductor device manufacturing method. FIG. 3A is a cross-sectional view showing a state of the p-type semiconductor layer being formed on the semiconductor wafer. FIG. 3B is a cross-sectional view showing a state of the oxide film being formed. FIG. 3C depicts a state of the metal underlayer on the anode side being formed.

As shown in FIG. 3A, at the start of manufacturing of the semiconductor device 100, a silicon wafer 90 is prepared. Before the state shown in FIG. 3A is created, an oxide film (not illustrated) is formed on the surface of the silicon wafer 90 by thermal oxidation. The silicon wafer 90 having the oxide film formed on its surface is subjected to a photolithography step. At the photolithography step, a resist material is applied to the surface of the silicon wafer 90, the surface carrying the oxide film formed thereon. Then, the resist material is exposed to light to develop a resist of a given pattern. An exposed region not protected with the resist is etched, which eliminates the oxide film from a region where the semiconductor element 150 is formed.

Subsequently, the region from which the oxide film is eliminated is doped with a p-type impurity, such as boron or aluminum. Then, the resist is removed and annealing is carried out. As a result, the p-type semiconductor layer 108a is formed in a prescribed region on the upper surface of the silicon wafer 90, as shown in FIG. 3A. Because of the high specific resistance of the silicon wafer 90, forming the p-type semiconductor layer 108a on one surface of the silicon wafer 90 results in formation of an n-type semiconductor layer (n⁻-type drift layer 108b) on the other surface.

Subsequently, as shown in FIG. 3B, the oxide film 110 is formed on the one surface side of the silicon wafer 90. The oxide film 110 can be formed by, for example, thermal oxidation, CVD, or the like. When the oxide film 110 is subjected to the same photolithography step and etching step as the silicon wafer 90 is subjected to, a part of the oxide film 110 is eliminated to form the contact region for connecting the p-type semiconductor layer 108a to the metal underlayer 109.

Subsequently, as shown in FIG. 3C, the metal underlayer 109 is formed on a surface of the p-type semiconductor layer 108a. The metal underlayer 109 can be formed by, for example, sputtering, vapor deposition, CVD, or the like. When the metal film formed is subjected to the same photolithography step and etching step as the silicon wafer 90 is subjected to, the metal underlayer 109 in the form of a patterned layer can be obtained.

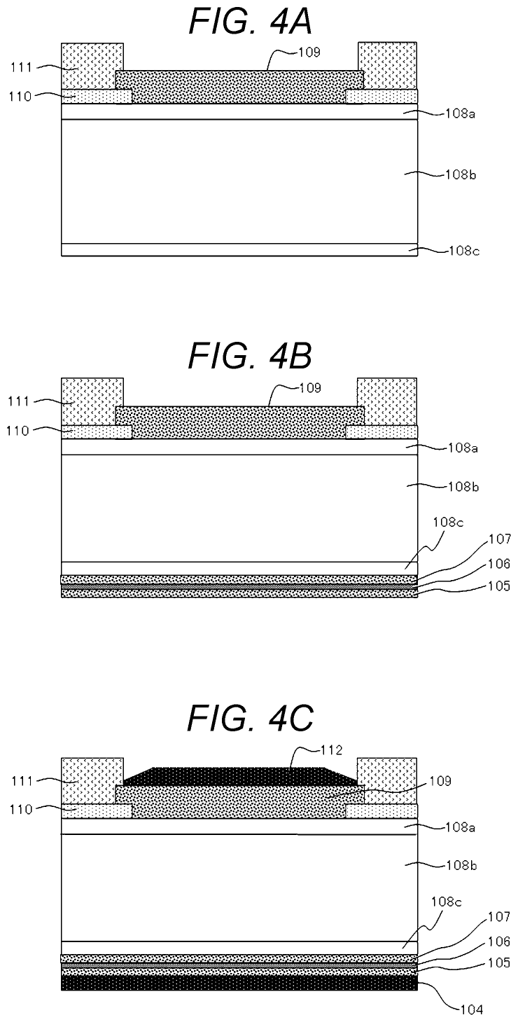

Subsequently, the resin layer 111 is formed on a surface of the oxide film 110 encircling the metal underlayer 109. The resin layer 111 can be formed, for example, by a method of applying a solution containing a polyimide precursor and a photosensitive material to the surfaces of the oxide film 110 and the metal underlayer 109 and exposing the solution to light to polyimidize the oxide film 110 and the metal underlayer 109 When the termination region is exposed to light, the surroundings of the metal underlayer 109 is sealed with the resin layer 111, as shown in FIG. 4A.

FIGS. 4A to 4C depict the semiconductor device manufacturing method. FIG. 4A shows a state of the resin layer being formed. FIG. 4B shows a state of the metal underlayer on the cathode side being formed. FIG. 4C shows a state of the plating layer on the anode side and the plating layer on the cathode side being formed.

As shown in FIG. 4A, a lower surface of the n⁻-type drift layer 108b is doped with an n-type impurity, such as phosphorus and arsenic. The lower surface is then annealed with a laser or the like. As a result, an n⁺-type drift layer 108c containing an n-type impurity higher in concentration than an n-type impurity in the n⁻-type drift layer 108b is formed on the lower surface of the silicon wafer 90. The n⁻-type drift layer 108b and the n⁺-type drift layer 108c provide a depletion layer. The lower surface of the n⁻-type drift layer 108b is ground to reduce the wafer thickness before being doped with the n-type impurity.

Subsequently, as shown in FIG. 4B, the metal layer 107 is formed on a surface of the n⁺-type drift layer 108c. In addition, the copper diffusion prevention layer 106 is formed on a surface of the metal layer 107. Further, the metal underlayer 105 is formed on a surface of the copper diffusion prevention layer 106. The metal layer 107, the copper diffusion prevention layer 106, and the metal underlayer 105 can be formed by, for example, sputtering, vapor deposition, CVD, or the like. When the metal underlayer 105 is made of an Al—Si alloy, for example, the thickness of the metal underlayer 105 can be determined to be about 2.0 μm.

As shown in FIG. 4C, the plating layer 104 is formed on a surface of the metal underlayer 105 on the cathode side. In addition, the plating layer 112 is formed on a surface of the metal underlayer 109 on the anode side. When the plating layers 104 and 112 are formed, a degree of development of spikes resulting from plating is estimated by the plating defects estimating method, and a material-to-be-plated having proper metal underlayers 105 and 109 formed in accordance with a spike development risk is used.

As shown in FIG. 1, when plating defects are estimated, the physical properties of respective surfaces of the metal underlayers 105 and 109 are measured first. Then, based on the measured physical properties of the surfaces of the metal underlayers 105 and 109, degrees of development of spikes on the metal underlayers 105 and 109, the spikes resulting from plating, are estimated. Thereafter, the estimated degrees of development of spikes are each compared with a reference value to determine whether the number of spikes expected to develop is large or small.

At the determining step S30, when the number of spikes expected to develop, i.e., the degree of development of spikes is estimated to be small, the plating layers 104 and 112 are formed under preset conditions. When the degree of development of spikes is estimated to be large at the determining step S30, however, formation of the plating layers 104 and 112 under the preset conditions is stopped. Instead of stopping formation of the plating layers 104 and 112, the plating pre-treatment step S130 with different pre-treatment details may be executed. For example, a resurfacing treatment, such as heat treatment on the surfaces of the metal underlayers 105 and 109, may be executed as an additional plating pre-treatment step, before the plating pre-treatment step S130 executed under the preset conditions. This plating pre-treatment step S130 is followed by the plating step S140, and the plating layers 104 and 112 are formed.

The plating layer 104 on the cathode side and the plating layer 112 on the anode side may be formed by either electrolytic plating or electroless plating. It is nevertheless preferable that both plating layers be formed by electroless plating. By adopting electroless plating, plating layers highly symmetric in thickness with each other can be formed on the cathode side and the anode side, respectively. The plating layers highly symmetric in thickness allows suppression of warping of the semiconductor element 150 caused by stress developing on the plating layers and thermal bending that occurs during plating for connecting wiring lines. Hence the manufacturability of the semiconductor device 100 can be improved.

It is preferable, from the viewpoint of preventing melting of the metal underlayers 105 and 109 during soldering for wire bonding or the like, that the thickness of each of the plating layers 104 and 112 be 1 μm or more and 10 μm or less. The thickness of each of the plating layers 104 and 112, however, may be increased to be over 10 μm.

When the thickness of the plating layers 104 and 112 is increased, the plating layers 104 and 112 may each include an additional layer of copper to have a multi-layer structure. When the plating layers 104 and 112 each h include an additional layer of copper, it is preferable that a copper diffusion prevention layer, which prevents thermally diffusing copper from entering the semiconductor substrate 108 as the copper diffusion prevention layer 106 does, be formed between the layer of copper and the semiconductor substrate 108.

In FIG. 4C, the plating layer is formed on both the cathode side and the anode side. However, the plating layer may be formed on the cathode side only or on the anode side only. When the plating layer is formed on one of the cathode and anode sides only, plating can be performed on the other of cathode and anode sides that has no plating film formed thereon, with a surface protective film pasted on the other of cathode and anode sides. The surface of each of the plating layers 104 and 112 may be further plated with gold or the like.

The semiconductor device 100 can be incorporated in a power module or the like, which is a major component of a power converter, such as an inverter. The power module can be used in various applications including drive power sources for hybrid vehicles, electric vehicles, railways, ships, and the like and power conditioners for use in power storage systems for natural energy power generation, such as solar power generation, wind power generation, or geothermal power generation, in stationary power storage systems, and in uninterruptible power supplies.

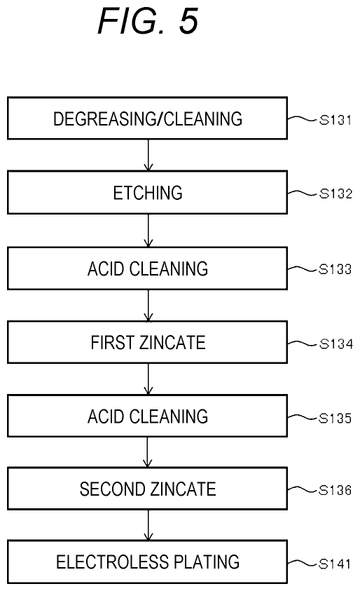

FIG. 5 is a flowchart of a process of electroless plating.

As shown in FIG. 5, the process of electroless plating includes a degreasing/cleaning step S131, an etching step S132, a first acid cleaning step S133, a first zincate step S134, a second acid cleaning step S135, a second zincate step S136, and an electroless plating step S141. As an example of the electroless plating step S141, a step of executing Ni—P electroless plating is cited.

The degreasing/cleaning step S131, the etching step S132, the first acid cleaning step S133, the first zincate step S134, the second acid cleaning step S135, and the second zincate step S136 make up the plating pre-treatment step S130. One or more of these steps may be omitted.

At the degreasing/cleaning step S131, the surface of the underlayer is degreased with an alkali degreasing agent to remove an oil component from the surface of the underlayer. As the alkali degreasing agent, for example, a solution containing an alkali substance like sodium hydroxide, a surfactant, or the like is used.

At the etching step S132, the surface of the underlayer is etched with, for example, a strong alkaline solution to remove an oxide film from the surface of the underlayer. As the strong alkali solution, for example, a solution containing an alkali substance like sodium hydroxide, a surfactant, a complexing agent, or the like is used.

At the first acid cleaning step S133, the surface of the underlayer is cleaned with an acid solution to remove an impurity, such as aluminum hydroxide (Al(OH)₃), produced by the removal of the oxide film. As the acid solution, a solution containing sulfuric acid, nitric acid, hydrofluoric acid, or the like is used.

At the first zincate step S134, the surface of the underlayer is immersed in a zincate liquid to deposit zinc on the surface of the underlayer. This deposited zinc is replaced with nickel during plating, so that a highly uniform plating film can be formed. As the zincate solution, for example, a solution containing zinc oxide, sodium hydroxide, iron chloride, or the like is used.

At the second acid cleaning step S135, the surface of the underlayer is cleaned with an acid solution to remove a part of the zinc deposited on the surface of the underlayer. As a result of removal of a part of the deposited zinc, a more uniform and denser zinc film can be formed at the second zincate step. As the acid solution, a solution containing nitric acid or the like is used.

At the second zincate step S136, the surface of the underlayer, from which a part of the deposited zinc has been removed, is immersed in a zincate solution to deposit zinc on the surface of the underlayer again. Depositing zinc again after removing a part of the deposited zinc makes the zinc film more uniform and denser, which therefore means that the uniformity and denseness of the plating metal replaced with zinc is improved. The second zincate step can be executed using the same zincate solution, treatment time, and treatment temperature as used at the first zincate step. The second zincate step, however, may take a treatment time shorter than that of the first zincate step.

At the electroless plating process shown in FIG. 5, a double zincate treatment is carried out. Because the metal underlayer 105 on the cathode side and the metal underlayer 109 on the anode side are made of aluminum or an aluminum alloy, an oxide film is easily formed on the surfaces of these underlayers. However, the double zincate treatment removes the oxide film from their surfaces, thus allowing formation of a plating film with high uniformity and denseness. As a result, adhesion between the metal underlayers 105 and 109 and the plating layers 104 and 112 can be enhanced.

At the electroless plating step S141, the plating layer is formed on the surface of the underlayer. As a plating solution, for example, a solution containing nickel salt such as nickel sulfate, hypophosphite such as sodium hypophosphite, a surfactant, a complexing agent, and the like is used. The thickness of the plating layer 104 on the cathode side and that of the plating layer 112 on the anode side can be determined to be, for example, about 3 μm.

Electroless nickel-phosphorus plating causes oxidation-reduction reaction expressed as the following formulas (1) and (2). The hypophosphite, which is a reducing agent, is oxidized and turns into phosphite, which releases electrons. Nickel ions are reduced into metal nickel. As a result, nickel containing phosphorus is deposited as a plating film.

$${H}_{2} {PO}_{{2}^{-}} + {H}_{2} O \to {H}_{2} {PO}_{{3}^{-}} + 2 {H}^{+} + 2 e - \qquad ( 1 )$$

$${Ni}^{2 +} + 2 {e}^{-} \to Ni \qquad ( 2 )$$

Examples of a plating solution used for electroless nickel-phosphorus plating include a low phosphorus concentration plating solution with phosphorus content of 1% to 4%, a medium phosphorus concentration plating solution with phosphorus content of 5% to 11%, and a high phosphorus concentration plating solution with phosphorus content of over 12%. Various plating films different in solder wettability, corrosion resistance, and the like can be obtained in accordance with variations in phosphorus content.

As a plating solution for formation of the plating layer 104 on the cathode side and the plating layer 112 on the anode side, for example, a low phosphorus concentration electroless nickel plating solution “TOP UBP Nicoron MLP” (manufactured by Okuno Chemical Industries Co., Ltd.) can be used. It should be noted, however, that for formation of these plating layers 104 and 112, any one of the low phosphorus concentration plating solution, the medium phosphorus concentration plating solution, and the high phosphorus concentration plating solution may be used in accordance with required characteristics of the plating film and the like.

Results of examination of a relationship between the physical properties of the surface of the underlayer and the degree of development of spikes will then be described with reference to drawings.

At the plating pre-treatment step S130, the surface of the underlayer made of metal is corroded by an alkali solution, an acid solution, a zincate solution, or the like. At the first zincate step S134 and the second zincate step S136, in particular, a strongly alkaline zincate liquid is used and therefore pitting corrosion of the surface of the underlayer is likely to occur. When the plating metal deposits in pits, spikes are formed. Development of spikes brings a concern that the adhesion of the plating film may drop or electrical short circuit may occur.

To clearly understand the relationship between the physical properties of the surface of the underlayer made of metal and the degree of development of spikes, the inventors fabricated a semiconductor wafer with the state of the surface of an underlayer being changed. The inventors performed electroless nickel-phosphorus plating on the semiconductor wafer, using the low phosphorus concentration plating solution, and then evaluated a degree of development of spikes made of nickel-phosphorus alloy.

The underlayer was formed of aluminum-silicon alloy by sputtering. An argon gas was used as a carrier gas. A plurality of types of test materials were fabricated. These test materials have their underlayers made different from each other in surface state by changing a flow rate of the carrier gas in a chamber and a film deposition rate, the flow rate and film formation rate being included in sputtering conditions. The film deposition rate was adjusted by adjusting the energy of a magnetron that generates an electromagnetic field.

A sputtered metal travels a longer mean free path as the flow rate of the carrier gas gets smaller, and consequently the particle diameter of the metal to deposit grows larger. In addition, the sputtered metal carries a greater kinetic energy as the film deposition rate gets higher, and consequently the particle diameter of the metal to deposit grows larger. The larger particle diameter of the metal making up the underlayer curbs the progress of local corrosion, which enhances s resistance to pitting corrosion. These facts lead to a conclusion that the smaller the flow rate of the carrier gas and the higher the film deposition rate, the less likely the spikes develop.

Because there is a correlation between the particle diameter of the metal and the reflectance on the surface of the metal, the brightness of the surface of the metal, and the crystallite diameter of the surface of the metal, it was assumed that by measuring the physical properties of the surface of the underlayer, the degree of development of spikes can be estimated. Thus, various semiconductor wafers, i.e., test materials with underlayers different in surface physical properties from each other were fabricated, and the physical properties of the surfaces of the underlayers of these test materials were measured as degrees of development of spikes in the test materials were evaluated. Through these processes, the validity of estimation of the degree of development of spikes was verified.

The degree of development of spikes was evaluated by observing a cross section of the plated underlayer. A cross section sample was prepared by cutting the semiconductor wafer having the underlayer formed thereon along a diameter line passing through the center of the wafer, embedding the cut semiconductor wafer in a resin, and performing polishing and ion milling on a cut surface. A cross section of the test material was observed with a scanning electron microscope (SEM)S-4300 or SU 8030 (manufactured by Hitachi High-Tech Co., Ltd.).

The degree of development of spikes was obtained as the number of spikes crossing each 1 μm-long segment of a virtual straight line along an interface between the underlayer and the plating layer, the interface being observed in a SEM image. The physical properties of the surface of the underlayer were measured by optical measurement or X-ray diffraction measurement. By optical measurement, the brightness of the surface of the underlayer or the reflectance on the surface of the underlayer was obtained. By X-ray diffraction, the crystallite diameter of the surface of the underlayer was obtained.

### <Measurement of Brightness of Surface of Underlayer>

The brightness of the surface of the underlayer was measured with a spectrophotometer CM-2600d (manufactured by Konica Minolta). A xenon lamp was used as a light source. A standard light source D65 was used as an observation light source. As measurement positions, nine points on a diameter line passing through the center of an orientation flat of the semiconductor wafer were set, the nine points being lined up at equal intervals from an upper end to a lower end of the diameter line when the orientation flat is defined as the lower end. A measurement result obtained at the fifth point on the surface was adopted, the fifth point being at the center among the nine points.

In general, methods of measuring reflected light include a specular component include (SCI) method by which specularly reflected light is included in measurements, and a specular component exclude (SCE) method by which specularly reflected light excluded from measurements. In is measurement of the brightness of the surface of the underlayer, the SCI method generally used for controlling the color of the material itself was used. The brightness (SCI-L*) defined in the CIE L*a*b* color system was obtained by using the SCI method.

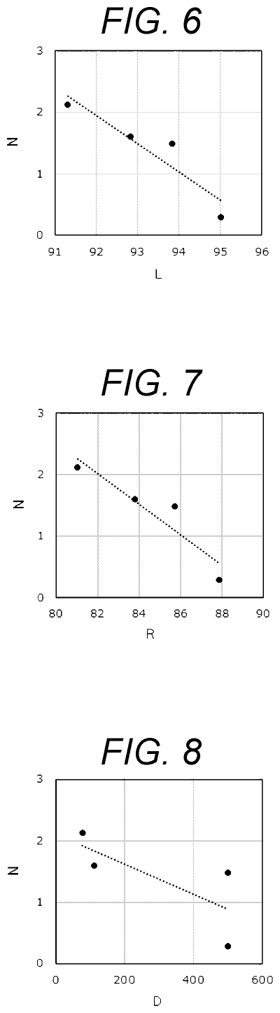

FIG. 6 depicts a relationship between measurement results of the brightness of the surface of the underlayer and evaluation results of the degree of development of spikes.

In FIG. 6, the vertical axis represents the number N of spikes [spikes/μm] per 1 μm-long segment of the interface between the underlayer and the plating layer, and the horizontal axis represents the brightness L (SCI-L*) of the surface of the underlayer.

FIG. 6 shows an obtained result demonstrating that the number of spikes per 1 μm-long segment of the interface between the underlayer and the plating layer decreases as the brightness of the surface of the underlayer increases. It can be said, therefore, that when the brightness of the surface of the underlayer is measured before the plating pre-treatment step, the degree of development of spikes, which are plating defects, can be estimated from a correlation between the brightness of the surface of the underlayer and the degree of development of spikes.

It is preferable from the viewpoint of ensuring the adhesion of the plating layer that the number of spikes per 1 μm-long segment of the interface between the underlayer and the plating layer be 1 or less. It is thus preferable under measurement conditions indicated in FIG. 6 that the brightness of the surface of the underlayer be 94 or more.

A light source different from a xenon lamp may also be used. Such light sources include a tungsten lamp, a deuterium discharge tube, a fluorescent lamp, a xenon flash lamp, a halogen lamp, a low-pressure mercury lamp, a laser excitation plasma light source, a laser light source, and a light-emitting diode (LED).

An observation light source different from the standard light source D65 may also be used. Such light sources include a standard light source A, a standard light source C, a standard light source D50, a standard light source F2, a standard light source F6, a standard light source F7, a standard light source F8, a standard light source F10, a standard light source F11, and a standard light source F12. The SCE method may be used as the measurement method, providing that sufficiently high brightness is ensured by measurement by the SCE method A color system different from the CIE L*a*b* color system may also be used. Such color systems include a CIE L*c*h*, a Hunter Lab color system and a CIE L*u*v* color system.

The measurement position may be any given position on the surface of the underlayer. It is preferable, however, that from the viewpoint of estimating development of spikes more accurately, the measurement position be a position at which the brightness of the surface is low and therefore spikes are readily develop. When development of spikes on a semiconductor wafer having underlayers formed on its both surfaces is estimated, the measurement position may be on the front surface of the semiconductor wafer or on the back surface of the semiconductor wafer.

When development of spikes on the semiconductor wafer is estimated, the measurement position may be on the surface of the underlayer in a central part of the semiconductor wafer or on the surface of the underlayer in a peripheral part of the semiconductor wafer. The central part of the semiconductor wafer and the peripheral part of the same may be different from each other in film deposition conditions for the underlayer. If measurement is made on a side where spikes are more likely to develop, it increases the accuracy of estimation of the degree of development of spikes.

When the degree of development of spikes on a target sample is estimated, a correlation between the brightness of the surface of the metal underlayer and the degree of development of spikes, i.e., the number of spikes per unit length or unit area of the interface between the underlayer and the plating layer is obtained in advance, using a reference sample. As the reference sample, a semiconductor wafer carrying an underlayer identical in chemical composition with the underlayer of the target sample is used. The correlation is obtained separately for individual conditions under which different light sources, observation light sources, measurement methods, color systems, measurement positions, and the like are used.

### <Measurement of Reflectance on Surface of Underlayer>

The reflectance on the surface of the underlayer was measured using a spectrophotometer CM-2600d (manufactured by Konica Minolta). A xenon lamp was used as a light source. A standard light source D65 was used as an observation light source. As measurement positions, nine points on a diameter line passing through the center of an orientation flat of the semiconductor wafer were set, the nine points being lined up at equal intervals from an upper end to a lower end of the diameter line when the orientation flat is defined as the lower end. A measurement result obtained at the fifth point on the surface was adopted, the fifth point being at the center among the nine points.

In measurement of the reflectance on the surface of the underlayer, the SCI method generally used for controlling the color of the material itself was used. The reflectance of reflected light with a wavelength of 600 nm was obtained by the SCI method. The reflectance of light reflection by aluminum shows a substantially positive correlation with the wavelength. The wavelength of 600 nm is a condition under which a relatively high reflectance can be obtained in the case of using a normal light source.

FIG. 7 depicts a relationship between measurement results of the reflectance on the surface of the underlayer and evaluation results of the degree of development of spikes.

In FIG. 7, the vertical axis represents the number N of spikes [spikes/μm] per 1 μm-long segment of the interface between the underlayer and the plating layer, and the horizontal axis represents the reflectance R [%] of reflected light with a wavelength of 600 nm on the surface of the underlayer.

FIG. 7 shows an obtained result demonstrating that the number of spikes per 1 μm-long segment of the interface between the underlayer and the plating layer decreases as the reflectance on the surface of the underlayer increases. It can be said, therefore, that when the reflectance on the surface of the metal underlayer is measured before the plating pre-treatment step, the degree of development of spikes, which are plating defects, can be estimated from a correlation between the reflectance on the surface of the underlayer and the degree of development of spikes.

It is preferable from the viewpoint of ensuring the adhesion of the plating layer that the number of spikes per 1 μm-long segment of the interface between the underlayer and the plating layer be 1 or less. It is thus preferable under measurement conditions indicated in FIG. 7 that the reflectance on the surface of the underlayer be 86% or higher.

A light source different from a xenon lamp may also be used. Such light sources include a tungsten lamp, a deuterium discharge tube, a fluorescent lamp, a xenon flash lamp, a halogen lamp, a low-pressure mercury lamp, a laser excitation plasma light source, a laser light source, and a light-emitting diode (LED).

An observation light source different from the standard light source D65 may also be used. Such light sources include a standard light source A, a standard light source C, a standard light source D50, a standard light source F2, a standard light source F6, a standard light source F7, a standard light source F8, a standard light source F10, a standard light source F11, and a standard light source F12.

As reflected light different from the reflected light with the wavelength of 600 nm, reflected light with any given wavelength can be measured, proving that it is hardly absorbed by the metal making up the underlayer. The wavelength region of reflected light may belong to any one of a UV-ray region, a visible light region, and an infrared light region. In addition to a spectrophotometer, a total reflectance meter, a spectral reflectance meter, or the like, may also be used to measure reflected light.

The measurement position may be any given position on the surface of the underlayer. It is preferable, however, that from the viewpoint of estimating development of spikes more accurately, the measurement position be a position at which the reflectance on the surface is low and therefore spikes are readily develop. When development of spikes on a semiconductor wafer having underlayers formed on its both surfaces is estimated, the measurement position may be on the front surface of the semiconductor wafer or on the back surface of the semiconductor wafer.

When development of spikes on the semiconductor wafer is estimated, the measurement position may be on the surface of the underlayer in a central part of the semiconductor wafer or on the surface of the underlayer in a peripheral part of the semiconductor wafer. The central part of the semiconductor wafer and the peripheral part of the same may be different from each other in film deposition conditions for the underlayer. If measurement is made on a side where spikes are more likely to develop, it increases the accuracy of estimation of the degree of development of spikes.

When the degree of development of spikes on a target sample is estimated, a correlation between the reflectance on the surface of the metal underlayer and the degree of development of spikes, i.e., the number of spikes per unit length or unit area of the interface between the underlayer and the plating layer is obtained in advance, using a reference sample. As the reference sample, a semiconductor wafer carrying an underlayer identical in chemical composition with the underlayer of the target sample is used. The correlation is obtained separately for individual conditions under which different light sources, observation light sources, measurement methods, measurement positions, and the like are used.

### <Measurement of Crystallite Diameter of Surface of Underlayer>

The crystallite diameter of the surface of the underlayer was measured using an X-ray diffraction (XRD) measuring device (RINT 2500 HL manufactured by Rigaku Corporation). In a measured X-ray diffraction spectrum, a peak with the highest diffraction intensity was found to be a diffraction peak caused by the (200) plane of aluminum. The crystallite diameter of the surface of the underlayer was obtained, using the full width at half maximum of the spectrum at the diffraction peak.

The crystallite diameter of the surface of the underlayer was determined by using a Scherrer method. The crystallite diameter D [nm] of metal crystallites present on the surface of the underlayer satisfies the following equation (I), which is a Scherrer formula.

D=K·λ/β·cosθ (I)

In the equation (I), K denotes a constant, λ denotes a wavelength [nm] of an X-ray, β denotes full width at half maximum [rad], and θ denotes a Bragg angle [rad].

FIG. 8 depicts a relationship between measurement results of the crystallite diameter of the surface of the underlayer and evaluation results of the degree of development of spikes.

In FIG. 8, the vertical axis represents the number N of spikes [number/μm] per 1 μm-long segment of the interface between the underlayer and the plating layer, and the horizontal axis represents the crystallite diameter D [nm] of aluminum on the surface of the underlayer.

FIG. 8 shows an obtained result demonstrating that the number of spikes per 1 μm-long segment the interface between the underlayer and the plating layer decreases as the crystallite diameter of the surface of the underlayer increases. It can be said, therefore, that when the crystallite diameter of the surface of the underlayer is measured before the plating pre-treatment step, the degree of development of spikes, which are plating defects, can be estimated from a correlation between the crystallite diameter of the surface of the underlayer and the degree of development of spikes.

It is preferable from the viewpoint of ensuring the adhesion of the plating layer that the number of spikes per 1 μm-long segment of the interface between the underlayer and the plating layer be 1 or less. It is thus preferable under measurement conditions indicated in FIG. 8 that the crystallite diameter of the surface of the underlayer be equal to or larger than 400 nm.

The crystallite diameter of the surface of the underlayer may be determined by using a Hall method. The crystallite diameter D [nm] of metal crystallites present on the surface of the underlayer satisfies the following equation (II), which is a Williamson-Hall formula.

$$β \cdot cos ⊖ / λ = 2 ε \cdot sin ⊖ / λ + K \cdot D \qquad ( II )$$

In the equation (II), K denotes a constant, λ denotes a wavelength [nm] of an X-ray, β denotes full width at half maximum [rad], θ denotes a Bragg angle [rad], and ¿ denotes lattice distortion.

As a diffraction line for aluminum, a diffraction line by a diffraction plane defined by a proper Miller index, such as a (200) plane and a (220) plane, can be used, providing that using the diffraction line allows obtaining a proper diffraction peak. When the underlayer is made of a metal different aluminum, a diffraction line corresponding to the metal making up the underlayer can be used. However, from the viewpoint of more accurately estimating development of spikes, using a diffraction line that offers higher diffraction intensity is preferable.

The measurement position may be any given position on the surface of the underlayer. It is preferable, however, that from the viewpoint of estimating development of spikes more accurately, the measurement position be a position at which the crystallite diameter of the surface is small and therefore spikes are readily develop. When development of spikes on a semiconductor wafer having underlayers formed on its both surfaces is estimated, the measurement position may be on the front surface of the semiconductor wafer or on the back surface of the semiconductor wafer.

When development of spikes on the semiconductor wafer is estimated, the measurement position may be on the surface of the underlayer in a central part of the semiconductor wafer or on the surface of the underlayer in a peripheral part of the semiconductor wafer. The central part of the semiconductor wafer and the peripheral part of the same may be different from each other in film deposition conditions for the underlayer. If measurement is made on a side where spikes are more likely to develop, it increases the accuracy of estimation of the degree of development of spikes.

When the degree of development of spikes on a target sample is estimated, a correlation between the crystallite diameter of the surface of the underlayer and the degree of development of spikes, i.e., the number of spikes per unit length or unit area of the interface between the underlayer and the plating layer is obtained in advance, using a reference sample. As the reference sample, a semiconductor wafer carrying an underlayer identical in chemical composition with the underlayer of the target sample is used. The correlation is obtained separately for individual conditions under which different types of diffraction lines, calculation methods, measurement positions, and the like are used.

As shown in FIGS. 6, 7, and 8, as a result of measurement of the physical properties of the surface of the underlayer, it has been confirmed that the degree of development of spikes has a correlation with the reflectance on the surface of metal, the brightness of the surface of metal, and the crystallite diameter of the surface of metal. It has been thus confirmed that when physical properties of a material-to-be-plated of which the degree of development of spikes is unknown, that is, the reflectance on the surface of metal, the brightness of the surface of metal, or the crystallite diameter of the surface of metal is measured, the degree of development of spikes can be estimated by applying the measured physical properties to a correlation obtained by using a plating material of which the degree of development of spikes is known.

The plating defects estimating method according to this embodiment can be widely applied to various plating defects. By the plating defects estimating method, not only the spike phenomenon, in which the plating film enters in pits on the base surface in a pattern of projections, needle shapes, etc., but also other plating defects caused by erosion-corrosion, crevice corrosion, or the like can be estimated, providing that the correlation between the physical properties of the surface of the underlayer and the degree of development of plating defects can be used.

According to the plating defects estimating method and the semiconductor device manufacturing method of this embodiment described above, the degree of development of spikes resulting from plating can be estimated from the physical properties of the base surface before formation of the plating film. Estimation of the degree of development of spikes can be made based on non-destructive measurement. Because plating only the material-to-be-plated assumed to develop fewer spikes is possible, a highly reliable semiconductor device and a manufacturing method for such a semiconductor device can be provided. Because the product yield is improved, the semiconductor device or the like can be provided at low cost. Furthermore, because a drop in the adhesion of the plating film and electrical short circuit via the underlayer hardly occur, a power converter equipped with the semiconductor device can be made more compact and highly reliable.

While the present invention has been described above, the present invention is not limited to the above-described embodiment and may be modified into various forms within a range not departing from the subject of the present invention. For example, the present invention is not necessarily limited to an embodiment including all constituent elements included in the above-described embodiment. Some of constituent elements of a certain embodiment may be replaced with other constituent elements, may be added to another embodiment, or may be omitted.

### REFERENCE SIGNS LIST

90 silicon wafer
100 semiconductor device
101 insulating substrate
102 conductive member
103 junction layer
104 plating layer
105 metal underlayer
106 copper diffusion prevention layer
107 metal layer
108 semiconductor substrate
108a p-type semiconductor layer
108b n⁻-type drift layer
108c n-type drift layer
109 metal underlayer
110 oxide film
111 resin layer
112 plating layer
113 cathode electrode
114 anode electrode
150 semiconductor element

1. A plating defects estimating method comprising:
a measuring step of measuring physical properties of a surface of an underlayer before a plating pre-treatment step of carrying out a plating pre-treatment on the underlayer; and
an estimating step of estimating a degree of development of spikes on the underlayer, the spikes resulting from plating, based on the measured physical properties.

2. The plating defects estimating method according to claim 1, wherein
the measuring step is a step of making optical measurement on a surface of the underlayer.

3. The plating defects estimating method according to claim 2, wherein
when reflectance on a surface of the underlayer is equal to or larger than a threshold, the degree of development of spikes is estimated to be low.

4. The plating defects estimating method according to claim 2, wherein
when brightness of a surface of the underlayer is equal to or larger than a threshold, the degree of development of spikes is estimated to be low.

5. The plating defects estimating method according to claim 1, wherein
the measuring step is a step of making X-ray diffraction measurement on a surface of the underlayer.

6. The plating defects estimating method according to claim 5, wherein
when a crystallite diameter of a surface of the underlayer is equal to or larger than a threshold, the degree of development of spikes is estimated to be low.

7. The plating defects estimating method according to claim 1, wherein
the underlayer is made of aluminum or aluminum alloy.

8. The plating defects estimating method according to claim 1, wherein
the plating is nickel plating or nickel alloy plating.

9. A semiconductor device manufacturing method, comprising:
an underlayer forming step of forming an underlayer on a surface of a semiconductor wafer;
a plating pre-treatment step of carrying out a plating pre-treatment on the underlayer;
a plating step of plating the underlayer subjected to the pre-treatment;
a measuring step of measuring physical properties of a surface of the underlayer before the plating pre-treatment step; and
an estimating step of estimating a degree of development of spikes on the underlayer, the spikes resulting from plating, based on the measured physical properties.

10. The semiconductor device manufacturing method according to claim 9, wherein
the measuring step is a step of measuring physical properties of a surface of the underlayer in a central part of the semiconductor wafer.

11. The semiconductor device manufacturing method according to claim 9, wherein
the measuring step is a step of measuring physical properties of a surface of the underlayer in a peripheral part of the semiconductor wafer.

12. The semiconductor device manufacturing method according to claim 9, wherein
when the degree of development of spikes, the degree of development being estimated at the estimating step, is larger than a given threshold, the plating pre-treatment step and the plating step are stopped.

13. The semiconductor device manufacturing method according to claim 9, wherein
details of the plating pre-treatment step are made different between a case where the degree of development of spikes, the degree of development being estimated at the estimating step, is larger than a given threshold and a case where the degree of development of spikes is smaller than the given threshold.
